(19) United States
(12) Patent Application Publication
(10) Pub. No.: US 2024/0282746 A1
(43) Pub. Date: Aug. 22, 2024

(54) METHOD FOR ESTABLISHING AN ELECTRIC CONNECTION TO AN ELECTRONIC COMPONENT AND A CHIP ASSEMBLY

(71) Applicant: TDK Electronics AG, München (DE)

(72) Inventors: Gerhard HOJAS, Söding-St. Johann (AT); Siegfried LAMPL, Eibiswald (AT); Lamablawa Mario Valentino ALFARRO SAMON MASAN, Wies (AT)

(21) Appl. No.: 18/569,905

(22) PCT Filed: Jun. 24, 2022
(86) PCT No.: PCT/EP2022/067392

§ 371 Date: Dec. 13, 2023

(30) Foreign Application Priority Data
Jul. 7, 2021 (DE) 10 2021 117 573.9

(51) Int. Cl. H01L 23/00

(52) U.S. Cl. CPC H01L 24/81; H01L 24/97; H01L 2224/81203; H01L 2224/81224; H01L 2224/97

(57) ABSTRACT

The present application addresses a method for establishing an electronic connection to an electronic component and a chip assembly. The method comprises the following steps. First, an electronic component having a first welding part is provided. Also a first electrical contact piece is provided. The first welding part and the first electrical contact piece are brought into mechanical contact with each other. Subsequently, while the mechanical contact is maintained, a welding current is applied which is capable of welding the electrical contact piece and the welding part together.

### CROSS-REFERENCE TO RELATED APPLICATIONS

This application is a U.S. National Stage of International Application No. PCT/EP2022/067392, filed Jun. 24, 2022, which claims the benefit of Germany Patent Application No. 102021117573.9, filed Jul. 7, 2021, both of which are incorporated herein by reference in their entireties.

### FIELD

The present application addresses a method for establishing an electronic connection to an electronic component and a chip assembly.

### BACKGROUND

Electrically connecting electronic components such as semiconductor components, electronic chips, varistors or thermistors, is relevant over the entire technical field of electronics.

In particular, there is a demand in the field for providing highly reliable electrical connections to electronic components by processes as simple as possible.

### SUMMARY

Therefore it is an object of the patent invention, as characterized in claim 1, to provide a method which at least partly solves the above-mentioned problems. Furthermore, a chip assembly is provided. Advantageous embodiments can be found in other claims.

According to a first embodiment, a method is provided for establishing an electric connection and the method comprises the following steps. First, an electronic component having a first welding part is provided. Also a first electrical contact piece is provided. The first welding part and the first electrical contact piece are brought into mechanical contact with each other. Subsequently, while the mechanical contact is maintained, a welding current is applied which is capable of welding the electrical contact piece and the welding part together.

As a current is used to weld the first electrical piece and the first welding part together, according to an embodiment, the welding method is preferably resistance welding.

Herein the first welding part can be any resistance weldable part which may be assembled on an electronic component. According to an embodiment the welding part consists of a material which can be melted by resistive welding. According to an embodiment the first welding part comprises a metal.

According to an embodiment, the first electrical contact piece may be any type of electrical contact which is capable of electrically contacting the electronic component and which is suitable to be welded to the first welding part. Examples for the first electrical contact piece may be a wire-shaped, block-shaped, or platelet shaped contact piece, which can be brought into mechanical contact with the first welding part.

As both the first welding part and the first contact piece are suitable for being welded together by resistive welding, according to an embodiment, they are electrically conducting. According to an embodiment during the mechanical contact also a conductive contact is established. In the resistive welding the point of highest resistance in the welding circuit is at the interference between the first welding part and the first contact piece. Therefore the interface or a spot in the interface becomes hottest as the highest voltage drop of electric circuit occurs there. Therefore the materials at the interface may melt and fuse together.

According to an embodiment the electronic component is a microchip sized electronic component. For example it may have a size in the range of 0.09 mm² to 9 mm². According to an embodiment the electronic component can be any varistor or even more preferable it may be an NTC thermistor.

The method has the advantage of being capable of easily establishing an electrical connection between the first electrical contact piece and the first welding part.

According to an embodiment the welding step is carried out such that welding electrodes are attached to components electrically connected with the first welding part and the first electrical contact piece. Welding currents for electronic components may lie in a range of 10 A to 200 A. Voltages may lie in a range of 0.1 V to 10 V. Furthermore, the process does not require additional materials at the interface between the first electrical contact piece and the first welding part. Therefore it has an advantage over other technologies such as soldering or wire bonding, for example, which introduce additional materials or components to form an electric junction.

According to an embodiment the first welding part is part of a terminal electrode of the electronic component.

In other words, this means that the welding part may be an area or a region of a terminal electrode of the electronic component.

For example the terminal electrode might, for example, connect to internal electrodes. However, the terminal electrode is not limited to that but rather refers to any electrode which is applied on the outer surface of an electronic component and is suitable for incorporating the electronic device into an electronic circuit.

According to an embodiment the electronic component may have two terminal electrodes. In this case a first welding part can be present on the first terminal electrode and a second welding part can be present on the second terminal electrode. In this case a contact piece may be applied to both terminal electrodes according to the above method.

According to an embodiment it is furthermore preferred that the first electrical contact piece is a first contact pad or part of a first contact pad arranged on a carrier substrate.

According to an embodiment electronic components may be applied to or fixed on a carrier substrate. According to an embodiment the carrier substrate can be an insulating substrate which may comprise or consist of polymers or ceramics. For ceramics, for example, highly insulating alumina or aluminum nitride plates can be used.

This means that the method as described above can be applied to welding an electronic component having a welding part to a contact pad on a carrier substrate.

This requires the welding current to flow between the terminal electrode and the contact pad. In principle, according to an embodiment the manner of applying the welding current is not limited. For example it would be generally possible that the welding current can flow through the electronic component to the external electrode and then to the contact pad and then out of the contact pad via a welding contact. This may allow simple access from a side of the electronic component opposite to the welding interface. However, this approach is only suitable if the electronic component can withstand the welding current and voltage. However, in many cases this approach is not preferred as the welding current might damage the electronic component or might generate heat and thereby damage it. Therefore, according to an embodiment, it is preferred that the welding contact can be applied directly or indirectly only to the terminal electrode which is in mechanical and electrically conducting contact with the contact pad.

Applying this method on carrier substrates having contact pads is particularly favourable, as the contact pads may have a size, which allows for easy contacting for the welding. If the top side is defined as the side of the substrate on which the electronic component is assembled on, in a preferred configuration the electronic component has only partial overlap with the contact pad when viewed onto the top side. Thus it is possible that the part of the contact pad not overlapping with the electronic component can be contacted with reduced steric hindrance from the top side.

According to a further embodiment, it is preferred that mechanical contact is supported during welding by pressing together the welding part and the electrical contact piece.

According to an embodiment this means that the electronic component is at least lightly pressed onto the substrate whereby the terminal electrode is pressed against the contact pad on the substrate. Here and in the following this pressure can be addressed by the term “welding pressure”. The welding pressure is any pressure or force applied which is capable of keeping the contact piece and the welding part in contact. It may for example also include the weight of the electronic component. However, it is preferable that an additional force or pressure is applied as the welding pressure. This additional pressing force is preferably in a range of 0.1 N to 50 N.

Applying the welding pressure can ensure a good electric contact during the welding which ensures that the current is flowing efficiently. Furthermore, it can support or ensure that the materials of the first contact piece and the first welding part are in firm mechanical contact with each other which allows for the welding spot to also have a high mechanical durability. This can allow, not only to electrically connect, but also to efficiently mechanically connect the contact element to the welding part.

According to a further embodiment it is preferred that the first electrical contact piece and/or the first welding part comprise at least one welding bump or several welding bumps which is or are capable of channeling the welding current through it or them to create a local welding spot.

According to an embodiment the welding bumps are most preferably established on the contact piece. This is in particular favourable in the case of the contact pieces being part of a contact pad or being a contact pad as the contact pads may be formed by etching technologies which are also capable of forming welding bumps. Thus, the welding bumps do not require an additional process step and can be formed during the structuring of the contact pads.

In the context of this invention a “welding bump” is any extrusion of a surface to be welded which is capable of channeling a welding current to create a heat spot which becomes a welding spot.

In the meaning of the present application “channeling the welding current” refers to the welding current having to flow through a comparatively narrow spot, in particular a region with a very small cross-sectional diameter. By channeling the welding current to a welding spot the area of the interface which is in electrical contact is considerably smaller than in a case in which the surfaces would not have welding bumps. This has the advantage that the welding heat is only very localized which, on the one hand, ensures efficient heating of the metal which is melted and therefore welded efficiently and, on the other hand, may ensure that the electronic component has a reduced heat stress. If larger areas are in contact higher welding currents might be necessary, which increases the overall heat transferred to the electronic component.

According to an embodiment the welding bumps have sizes up to one-tenth of a millimeter as their average diameter.

According to an embodiment, even more preferably the welding bums are tip shaped, i.e. may have a conical or pyramid shape pointing away from the surface to be welded. Such shapes reduce the contact area and thus allow efficient channeling of the welding current.

Furthermore, according to an embodiment a first and a second welding spot are formed simultaneously by the same welding current. “Formed by the same welding current” may mean in particular that the first and the second welding spots are in serial connection concerning the welding current.

This setup is particularly preferable as it allows the welding current to be conducted to the welding part and again away from it by the contact piece which is to be welded to it. In such a configuration the welding electrode, which only applies the welding current during the process, does not have to directly access the terminal electrode, which faces the contact piece and may be difficult to access directly. Instead, a first welding spot can be created with a first contact piece and a second welding spot with a second contact piece.

According to an embodiment, this can in particular be preferably achieved in a case in which the first contact pad comprises or consists of two electrically separate sub-pads and these can be simultaneously brought into contact with the first welding part and a second welding part. According to an embodiment the first welding part and the second welding part are preferably electrically connected with each other. According to an embodiment it is preferred that both are part of the same terminal electrode. When a welding current is applied between the first sub-pad and the second sub-pad a welding spot is formed on each of the sub-pads and each of the welding parts. In this configuration the current can be guided by the terminal electrode from one sub-pad to the other. In other words the two sub-pads, which are electrically and spatially separated otherwise can be bridged by one terminal electrode of the electronic component.

According to an embodiment the welding step can be performed such that welding contacts of a welding machine may be applied on the sub-pads only. According to an embodiment, it is even more preferred that the welding contacts are applied to regions of the sub-pads which do not overlap with the electronic component. Thus a sterically simple access of the welding contacts to the sub-pads is enabled. Further this allows to avoid the sterically difficult procedure of directly contacting the terminal electrode.

According to an embodiment, the not overlapping regions of the sub-pads may be used for contacting the electronic component by wire bonding or other methods.

According to an embodiment, in particular during welding of a flip chip electronic component to a carrier substrate, the method described above can be applied subsequently or simultaneously to two terminal electrodes being welded to two separate contact pads on the same carrier substrate. The two terminal electrodes preferably are terminal electrodes of the electronic component.

Here and the following a “chip” refers to a setup in which terminal electrodes are arranged on an electronic component on opposite sides. Accordingly, a “chip setup” refers to a chip welded or connected to a carrier substrate with one of the terminal electrodes. The term “flip chip” refers to an electronic component in which two separate terminal electrodes are arranged on one side of the electronic component. This allows welding of the electronic component with both terminal electrodes to a substrate with accordingly arranged contact pads. Accordingly, the term “flip chip setup” refers to a setup in which a flip chip is welded with at least two terminal electrodes on the same side of the flip chip to contact pads on a carrier substrate.

According to an embodiment, the material of the welding part and the electrical contact may differ. In particular the material of an outer layer of each of the welding part and the electrical contact piece may be different.

However, according to an embodiment, it is preferred that the outermost metal of the welding part and the electrical contact piece are the same.

According to an embodiment, this can mean that either the entire material of each of the welding part and the electrical contact piece is the same or in the case of a layered electrode such as a layered terminal electrode or a layered contact pad the outermost layers are of the same material.

The advantage of having the same material is that both materials heat and melt equally for which a homogenous connection and therefore a good electric connection and mechanical connection may be established.

According to an embodiment the contact piece and/or the welding part comprises silver, gold, copper, nickel, molybdenum or tungsten. Of these, in particular silver, gold, copper and nickel are preferred. Particularly preferred are layered contact pads with a copper layer being in direct contact with the carrier substrate, with a nickel layer on top of the copper layer and a terminating layer of gold. Regarding the electronic component gold terminated terminal electrodes are preferred. Alternatively silver or silver-gold alloys or layered electrodes comprising these materials are also preferred.

According to an embodiment the method as laid out above may furthermore comprise providing an insulating carrier substrate and applying a metal layer on top of the insulating carrier substrate. The method for applying the metal layer can be chosen from any suitable method including printing or laminating the metal layer onto the substrate. Alternatively the metal layer may be sintered together with the substrate or be applied by physical vapour deposition, sputtering, galvanic deposition, or chemical electro plating. Next an etching step is applied in which the metal layer is structured. As etching methods dry etching or wet etching may be applied. In particular, during the etching step, several contact pads or sub-pads can be formed on the substrate. Furthermore during the etching, or in a separate etching step preferably at least one welding bump is formed per sub-pad.

According to an embodiment, a chip assembly is provided which can be formed by the above-described method. Therefore, all features and advantages disclosed for the method also apply to the chip assembly and vice versa.

According to an embodiment, the chip assembly comprises an electronic component assembled on a carrier substrate wherein a first contact pad of the substrate is welded to a first terminal electrode of the component to form an electrical connection.

This can mean, according to an embodiment, that a welding spot created by the resistive welding can be identified in the assembly which is electrically and preferably also mechanically connecting the terminal electrode and the contact pad. Such a connection is particularly advantageous as it is created by an advantageous method.

According to a further embodiment of the assembly, the contact pad encompasses two separate sub-pads and the terminal electrode is welded to both sub-pads.

In several cases having two sub-pads, which are electrically bridged by the terminal electrode, is not essentially required for integrating the electronic component in the assembly into a larger electronic circuit. In several cases only one contact to one of the sub-pads is sufficient for electrically accessing the electronic component in the assembly. This means one of the sub-pads may be redundant for incorporating the electronic component into an electronic circuit. However, the inventors have found that having two separate sub-pads is particularly advantageous for the welding method.

According to an embodiment the electronic component may comprise a second terminal electrode which is welded to a second contact pad on the carrier substrate.

According to an embodiment this configuration can be realized in a flip chip configuration. This may allow, for example, for an electronic component with two terminal electrodes that it can be fully contacted via the carrier substrate.

According to an embodiment it is also preferred that the second contact pad also consists of two separate sub-pads.

According to an embodiment the first contact pad is connected to connective means for integration of the chip assembly into an electronic circuit.

“Connective means” in the meaning of the present application refers to any electric connection or electronic connection which is capable of integrating the chip assembly or in particular the electronic component into an electronic circuit. For example, connective means include any internal or external connections on the substrate. According to an embodiment this may include, for example, conductive routes printed or otherwise applied to the substrate surface. Furthermore this also includes vias going through the substrate, for example to an opposing surface. This also includes any inner electrodes within the substrate which may be connected directly or indirectly. Bonding wiring as the connective means is particularly preferable for the present application. The preferred size of the sub-pads may be in the range of 1 to 0.5 mm². For such dimensions contacting by bonding wiring is particularly suited.

Furthermore, for the reasons described above it is preferred according to an embodiment that the outermost metal of the first terminal electrode and the first contact pad are the same.

As also described above, according to an embodiment for the process both the terminal electrode and the first contact pad may comprise silver, gold, copper, nickel, molybdenum or tungsten, from which silver, gold, copper or nickel are preferred.

Furthermore, according to an embodiment the use or integration of the electronic component into an electronic circuit is described. Preferably the connection for integration of the chip assembly or the electronic component into an electronic circuit is performed by one sub-pad of the first contact pad only.

As described above in more detail, this has a particular advantage, not for electronic connection, but for applying the welding method.

### BRIEF DESCRIPTION OF THE DRAWINGS

The invention is described in more detail below using exemplary embodiments. These exemplary embodiments are shown in the following figures, which are not to scale. Lengths as well as relative and absolute dimensions can therefore not be taken from the figures. Furthermore, the invention is not limited to the following embodiments.

FIG. 1 shows a first exemplary embodiment of a welding assembly in top view;

FIG. 2 shows the first exemplary embodiment of the welding assembly in side view;

FIG. 3 shows a first exemplary embodiment of a contacted welding assembly in top view;

FIG. 4 shows the first exemplary embodiment of the contacted welding assembly in side view;

FIG. 5 shows a second exemplary embodiment of a welding assembly in side view;

FIG. 6 shows a third exemplary embodiment of a welding assembly in side view;

FIG. 7 shows a fourth exemplary embodiment of a welding assembly in top view;

FIG. 8 shows the fourth exemplary embodiment of the welding assembly in side view;

FIG. 9 shows a second exemplary embodiment of a contacted welding assembly in top view;

FIG. 10 shows the second exemplary embodiment of the contacted welding assembly in side view;

FIG. 11 shows a first exemplary embodiment of a chip assembly in side view;

FIG. 12 shows the first exemplary embodiment of the chip assembly in top view;

FIG. 13 shows a third exemplary embodiment of a contacted welding assembly in top view;

FIG. 14 shows a second exemplary embodiment of a chip assembly in side view;

FIGS. 15 to 18 show process steps for forming contact pads.

### DETAILED DESCRIPTION

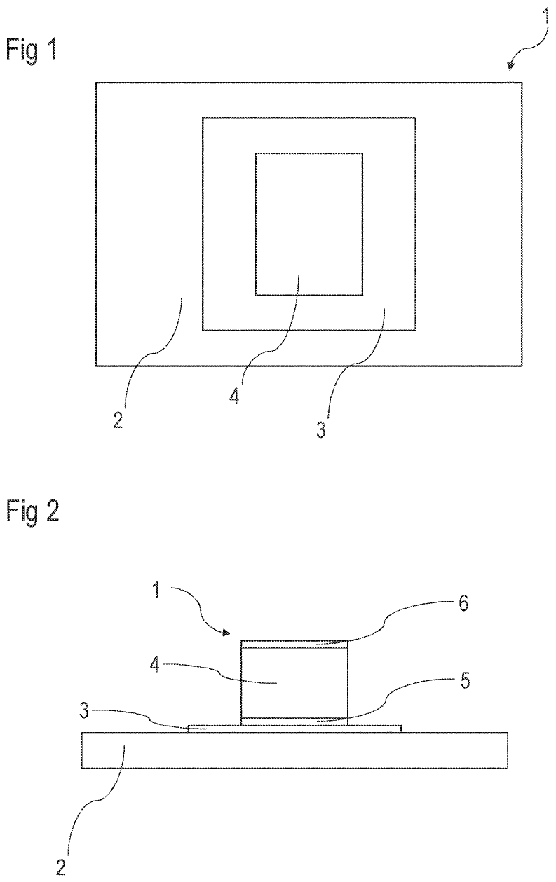

In FIG. 1 a first exemplary embodiment of a welding assembly 1 is shown in top view. FIG. 2 shows a side view of first the embodiment the welding assembly 1.

This first exemplary embodiment of the welding assembly 1 depicts an intermediate step of an embodiment of a process of establishing an electric connection.

For the welding assembly 1 a carrier substrate 2 is provided on which a first contact pad 3 is arranged. Furthermore, an electronic component 4 which has a first terminal electrode 5 and a second terminal electrode 6 is also provided. The electronic component 4 is assembled on the contact pad 3, while the first terminal electrode 5 is in mechanical contact with the first contact pad 3.

Generally the electronic component 4 can be any electronic component. Preferably, it is an NTC thermistor.

The carrier substrate 2 can be any suitable insulating substrate. Preferably the material of the carrier substrate 2 comprises or consists of alumina.

The first contact pad 3 is metallic and suitable for welding. Preferably it comprises silver, gold, copper, nickel, molybdenum or tungsten. In particular a layered first contact pad 3 is preferred with a copper layer in direct contact with the carrier substrate 2. A nickel layer may be assembled on top of the copper layer. Furthermore a terminating gold layer is assembled on top of the nickel layer.

Gold terminated electrodes are preferred for the first terminal electrode 5 and preferably also for the second terminal electrode 5. For example the electrode may be a layered electrode with the outermost layer being of gold.

The first terminal electrode 5 has been brought into mechanical contact with the first contact pad 3. Thereby an electrical contact can also be established. Therefore, the regions of the first terminal electrode 5 which are in contact with the first contact pad 3 are an example of a welding part.

Preferably bringing and maintaining the mechanical contact also includes or is supported by pressing the first terminal electrode 5 and the first contact pad 3 together. This can preferably be performed by having a force or a pressure pushing the electronic component 4 onto the fixed carrier substrate 2.

The region or regions of the first contact pad 3 being in contact with the first terminal electrode 5 can be regarded as a contact piece.

As can be seen in FIG. 1, the electronic component 4 only overlaps with a part of the first contact pad 3. The areas in which no overlap is established can be referred to as non-overlapping. This allows the first contact pad 3 to be contacted in the non-overlapping regions for different means from the top side. Here the top side is the side of the carrier substrate 2 on which the electronic component 4 is assembled on.

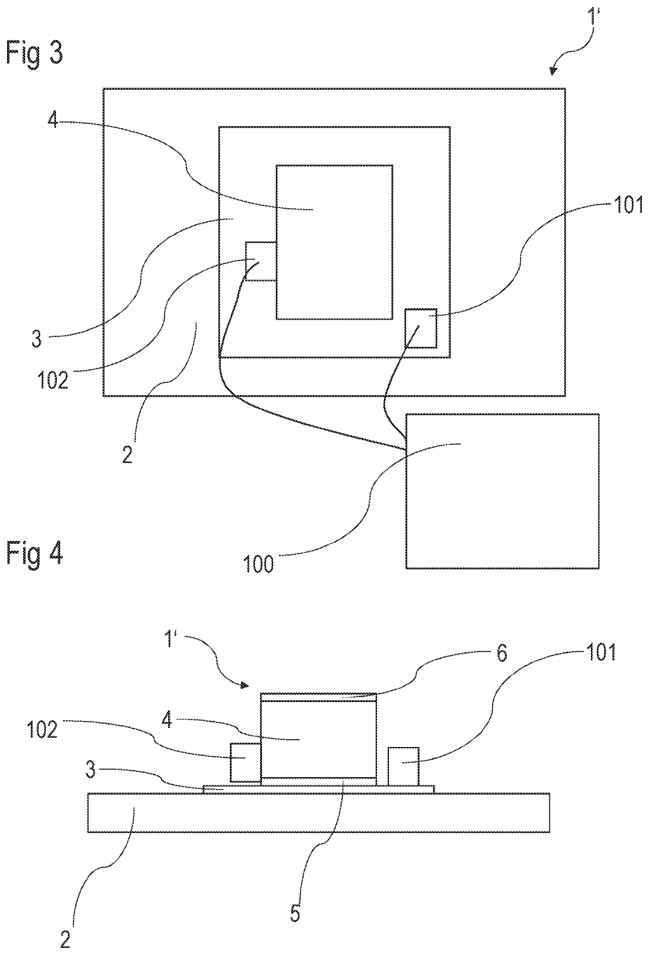

In FIGS. 3 and 4 a first exemplary embodiment of a contacted welding assembly 1′ is shown. The setup of the first exemplary embodiment of the contacted welding assembly 1′ is basically identical to the first exemplary embodiment of the welding assembly 1 as shown in FIGS. 1 and 2.

As the electronic component 4 overlaps only with a part of the contact pad 3, a first welding contact 101 can be applied in the non-overlapping part of the first contact pad 3. Furthermore, a second welding contact 102 electrically contacts the terminal electrode 5. Both are connected to a welding machine 100.

Thereby a welding circuit is established. By means of the welding circuit and while maintaining the mechanical contact between the first contact pad 3 and the first terminal electrode 5, a welding current can be applied by a welding machine 100. The welding current is generally not limited but is capable of welding the first terminal electrode 5 to the first contact pad 3. Preferably welding voltages in the range of 0.1 V to 10 V and welding currents in the range of 10 A to 200 A are used.

These welding conditions are suitable for preferred sizes of the assemblies or chip assemblies which may be produced by the method. Preferably the contact pads have sizes in the range of 0.05 to 3 mm². The electronic components may have sizes in the range of 0.05 to 1 mm². The size of the welding contacts can be in the range of 0.05 to 1 mm².

After the welding step, i.e. applying the welding current, the welding contacts 101 and 102 are detached from the components of the welding assembly.

As can be seen in FIG. 4, even for the schematic and non-to-scale drawing, attaching the second welding contact 102 to the first terminal electrode 5 may be challenging for reasons of steric hindrance. If the electronic component is capable of enduring welding currents, the second welding contact 102 could be attached to the second terminal electrode.

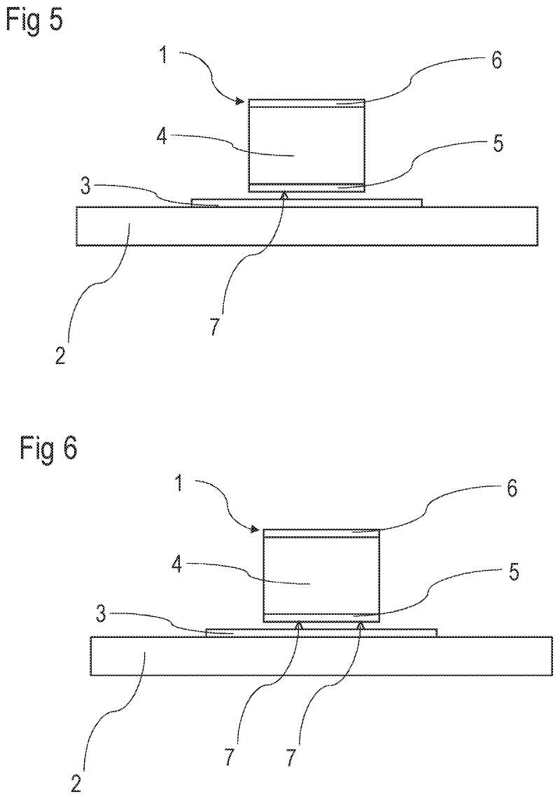

FIG. 5 shows a second exemplary embodiment of a welding assembly 1. The second exemplary embodiment of the welding assembly 1 mainly equals the first exemplary embodiment of a welding assembly as shown in FIGS. 1 and 2 except that a welding bump 7 is established on or as part of the contact pad 3. The welding bump 7 is oriented away from the contact pad 3. Furthermore, the welding bump 7 is in contact with the first terminal electrode 5. The welding bump 7 has average diameters of 0.1 mm or below.

As can be seen even in the schematic drawing when comparing FIGS. 5 and 2, the welding bump is capable of drastically reducing the contact area between the first terminal electrode and the first contact pad. Thereby the welding bump 7 is capable of channeling a welding current. This enables the material of the first contact pad 3 and also the material of the first terminal electrode 5 to be heated in this small contact area only. Thereby the materials at the welding contact point are melted efficiently and thus a mechanical and electrical welding connection can be established.

The welding bumps 7 are preferably part of the first contact pad 3. They generally refer to any extrusion of the contact pad which is capable of channeling the welding current. Preferably the welding bump 7 has a pyramidal or cone shape. Thereby a tip is provided which is narrow and may channel the welding current. Preferably the tip is considerably smaller than the average diameter of the welding bump 7. The tip has at least halve the average diameter of the welding bump 7.

A variation of this exemplary embodiment is shown in FIG. 6 as a third exemplary embodiment of welding assembly 1. FIG. 6 shows that on the first contact pad 3 more than one welding bump 7 can be established. As a representation of this two welding bumps 7 are depicted. Both are in contact with the first terminal electrode 5. Equivalently, a roughened surface may also be used. By the roughening the surface of the first contact pad several welding bumps 7 may be created through which the welding current can flow. Please note that in such a configuration as shown in FIG. 6, a parallel junction is created by the welding bumps 7 for the welding current.

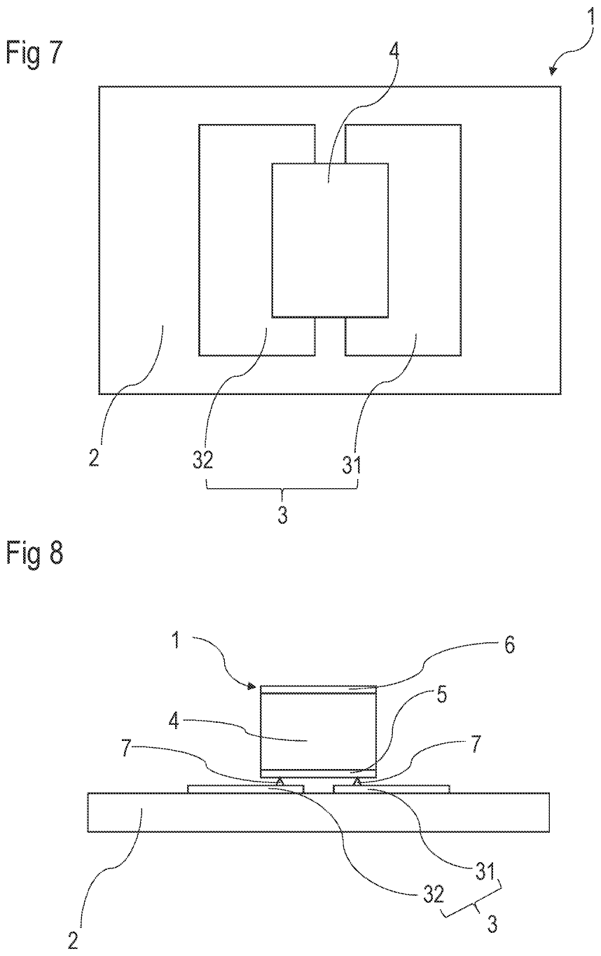

FIG. 7 shows a fourth exemplary embodiment of a welding assembly 1 in top view. Furthermore the fourth exemplary embodiment of the welding assembly 1 can be seen in side view in FIG. 8.

The components of the fourth exemplary embodiment of the welding assembly 1 mainly equal those of the first exemplary embodiment of the welding assembly except that the first contact pad 3 consists of two sub-pads, a first sub-pad 31 and a second sub-pad 32. Each of the sub-pads is modified by at least one welding bump 7 which is advantageous but not essential for the principle of this assembly. In the fourth exemplary embodiment of the welding assembly 1 the first sub-pad 31 and the second sub-pad 32 are spatially and electrically separate from each other, except for being bridged electrically by the first terminal electrode 5.

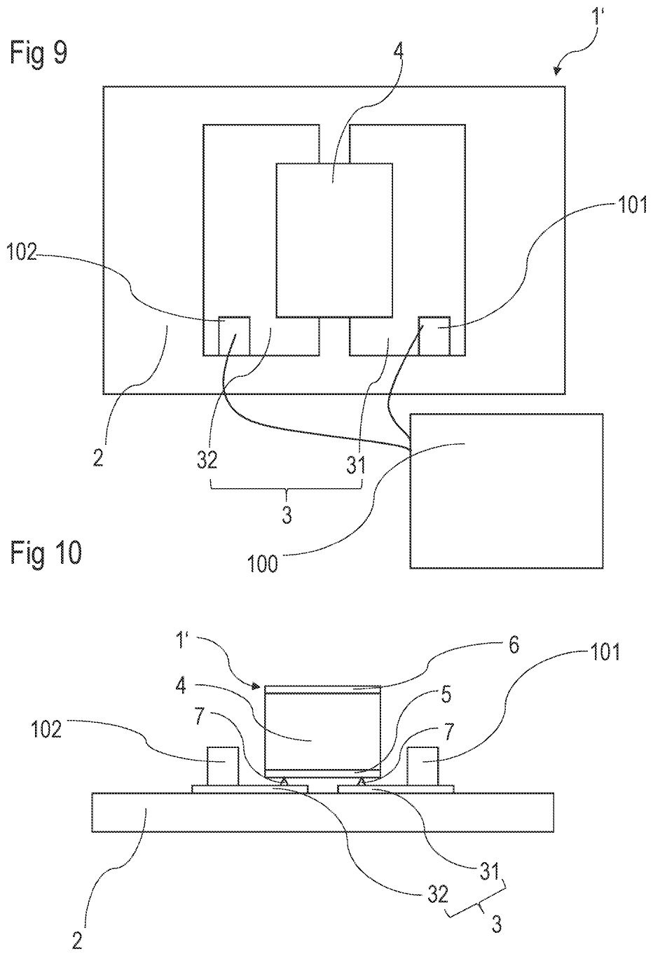

The advantage of this can best be seen in FIGS. 9 and 10, which show a second exemplary embodiment of a contacted welding assembly 1′ in top view in FIG. 9 and in side view in FIG. 10. Here the fourth exemplary embodiment of the welding assembly 1 as shown in FIGS. 7 and 8 is contacted by welding contacts 101 and 102 in partly similar way manner as shown for FIGS. 3 and 4.

In this configuration the first welding contact 101 is in contact with the first sub-pad 31. The second welding contact 102 is in contact with the second sub-pad 32. Both welding contacts are assembled on non-overlapping parts of each sub-pad, which is preferred for welding access form the top side.

If assumed a DC welding current would be applied by the welding machine 100 to which both welding contacts are connected, the welding current may flow from the first welding contact 101 through the first sub-pad 31 to the first terminal electrode 5. From there the welding current can flow to the second sub-pad 32 and then back to the welding machine via the second welding contact 102. Thus a welding circuit is established. Of course, depending on the type of current, i.e. AC or DC, a current direction may not be defined, however this exemplary description highlights that the points of contact, i.e. the welding bumps 7, are in a serial connection, as the first terminal electrode bridges the otherwise unconnected sub-pads 31 and 32.

This configuration has the advantage that the welding contacts do not have to be applied to the first terminal electrode 5 directly. However, they can be applied to non-overlapping areas which are areas of the sub-pads which are not overlapped by the electronic component 4 in top view. Thus, a simple access from the top side for the welding process step can be achieved.

FIG. 11 shows a first exemplary embodiment of a chip assembly 11 in side view. In the first exemplary embodiment of a chip assembly 11 the electronic component 4 has chip configuration as it has the first terminal electrode 5 and the second terminal electrode 6 on two opposing sides. This first exemplary embodiment of a chip assembly 11 may preferably be produced by the method including the setup as shown in FIGS. 7 and 8, and FIGS. 9 and 10. From the welding bumps welding spots 8 are formed by the welding. The welding spots 8 electrically and mechanically connect the terminal electrode 5 to the sub-pads 31 and 32.

Furthermore, one of the sub-pads, in this case the first sub-pad 31, can serve as a means for further electrical connection to integrate the chip assembly 11 into an electronic circuit. As shown in FIG. 11 this can be achieved by wire bonding, whereby the bonding wire 10 is depicted in FIG. 11. Alternative means which are not depicted include the means discussed in the introduction.

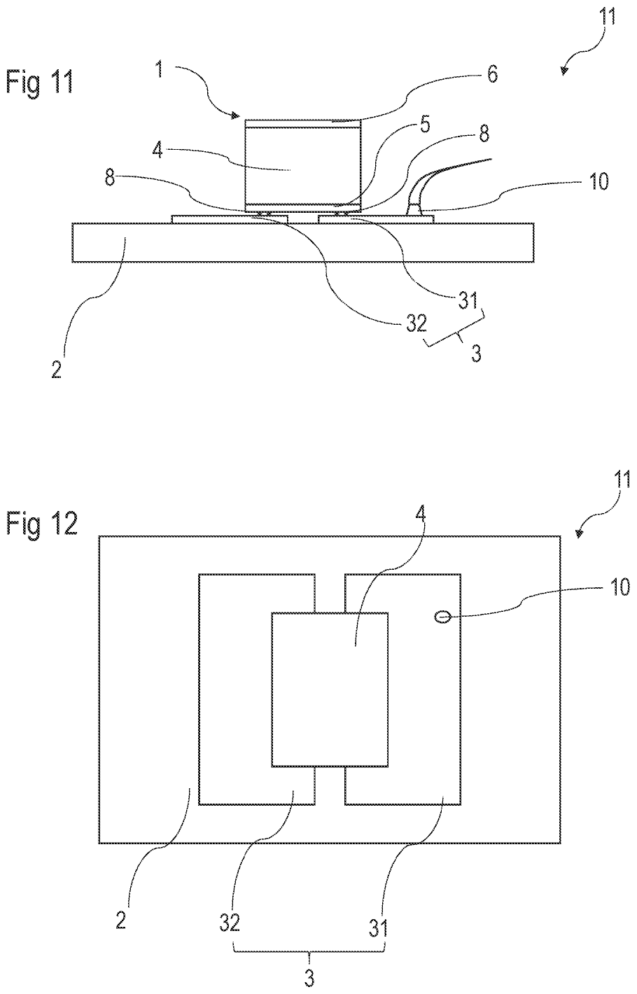

A top view of the first exemplary embodiment of the chip assembly can be seen in FIG. 12. FIG. 12 shows that also the wire bonding can be performed on non-overlapping regions of the first contact pad 3.

As can be seen in FIG. 11 the second sub-pad 32 can have no contribution in integrating the electronic component 4 into an electronic circuit. The second sub-pad 32 may be redundant for incorporating the electronic component 4 into an electronic circuit. It may have the sole purpose of applying the preferred welding process.

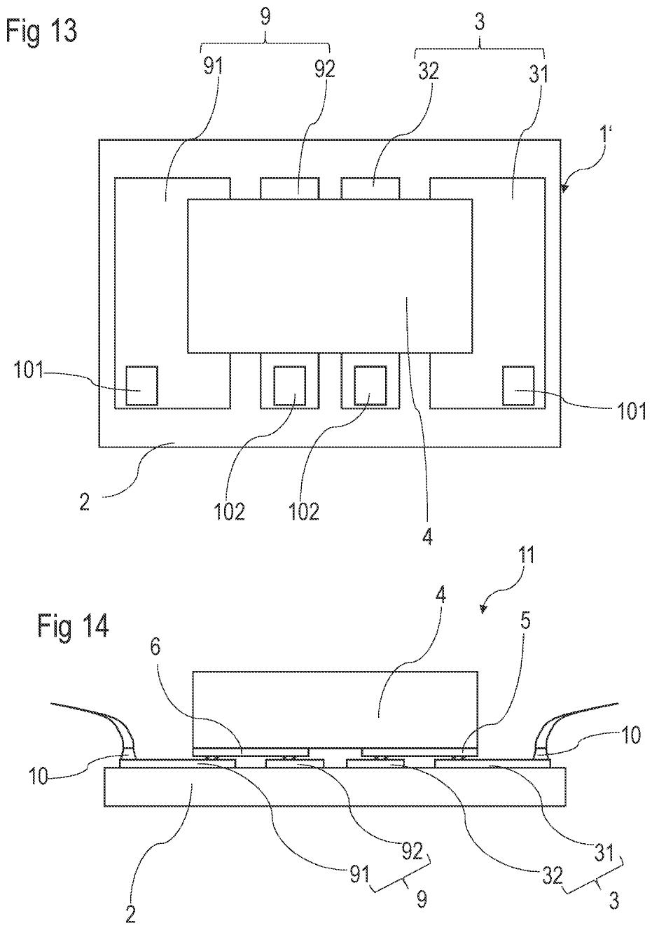

In a top view perspective FIG. 13 shows a third exemplary embodiment of a contacted welding assembly 1′. As can be seen, the welding contacting is in principle analogous for the contacting of the exemplary embodiment of FIG. 9. However, for the sake of simplicity, the schematic drawing of the welding machine is omitted in FIG. 13.

As can be seen for this exemplary embodiment of FIG. 13, two contact pads, a first contact pad 3 and a second contact pad 9 are realized on the substrate 2 as provided. The method as described in connection with FIGS. 7 to 10 allows contact to two separate terminal electrodes on the electronic component 5 facing the substrate.

For each of the contact pads 3 and 9 the welding contacts 101 and 102 are applied, one on a first sub-pad 31 or 91 and the other on a second sub-pad 32 or 92.

The welding performed on the first contact pad and the second contact pad can be performed simultaneous or after another.

FIG. 14 shows a second exemplary embodiment of a chip assembly 11, here in flip chip configuration, which may be produced by a method incorporating the step depicted in FIG. 13.

The electronic component 4 of FIG. 14 has a flip chip configuration, as both terminal electrodes 5 and 6 are arranged on the same side of the electronic component 4.

The electronic component 4 is assembled on the substrate 2. The carrier substrate 2 comprises the first contact pad 3 which itself consists of two spatially separated sub-pads, i.e. the first sub-pad 31 and the second sub-pad 32. Equivalently, on the carrier substrate 2 a second contact pad 9 is provided which consists of a first sub-pad 91 and a second sub-pad 92. The first sub-pad 31 and the second sub-pad 32 are electrically connected only by the bridging first terminal electrode 5 of the electronic component 4. Between both the first terminal electrode 5 and each of the sub-pads 31 and 32 welding spots are formed which are not explicitly labelled here for the sake of simplicity. Equivalently, the sub-pads 91 and 92 are bridged by the second terminal electrode 6 which is also facing the substrate. Welding spots are established analogously.

Furthermore, the first sub-pad 31 and the other first sub-pad 91 are each contacted in this assembly by a bonding wire 10 in order to integrate the chip assembly 11 including the electronic component 5 into an electronic circuit.

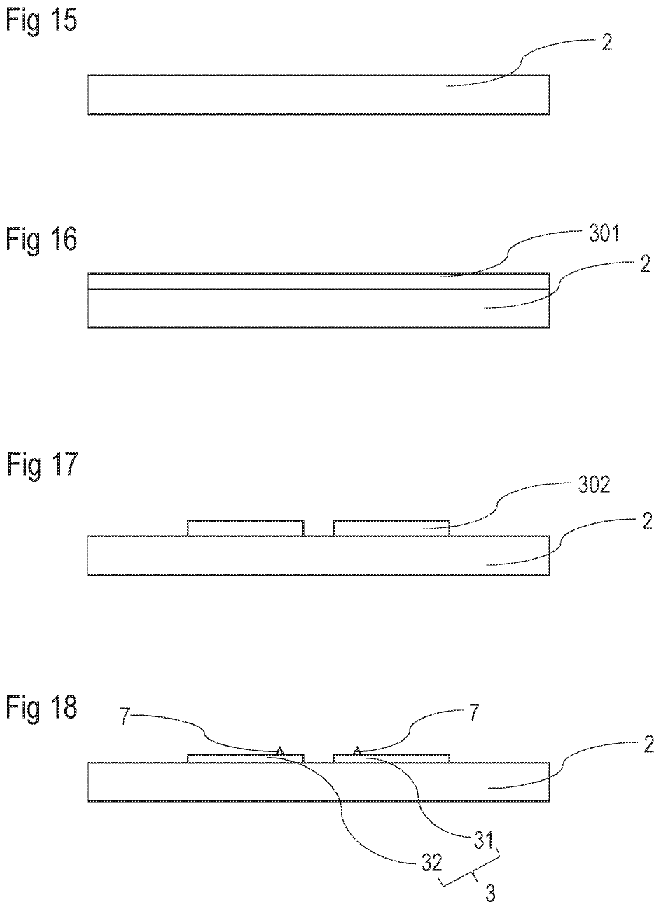

Finally, a part of a process of providing contact pads, or in particular a first contact pad comprising two sub-pads, is depicted in FIGS. 15 to 18.

As shown in FIG. 15, first a carrier substrate 2 is provided which is preferably an insulating substrate, for example consisting or comprising of alumina.

Subsequently as shown in FIG. 16 a metal layer 301 is deposited or applied to the substrate 2. Any suitable method can be used for applying the metal layer. Methods may include physical vapour deposition, methods using burnt-in electrodes, attaching metal foils, sputtering, galvanic deposition, or chemical electro plating.

Subsequently as shown in FIG. 17, the metal layer 301 is structured by a structuring method or preferably by an etching method, such as wet etching or dry etching. Thereby the structured metal layer 302 is created. As depicted, in such a step the contact pads, which each may comprise sub-pads, are already pre-established.

Furthermore, in a next step which can also be a sub-step of the previous etching step, welding bumps 7 are etched from the structured metal layer 302. It is preferred that the step shown in FIG. 18 is a sub-step of the previous etching step as thereby the number of process steps can be minimized, which can be more efficient.

### LIST OF REFERENCE SIGNS

1 welding assembly
1′ contacted welding assembly
2 carrier substrate
3 first contact pad
4 electronic component
5 first terminal electrode
6 second terminal electrode
7 welding bump
8 welding spot
9 second contact pad
10 bonding via
11 chip assembly
31 first sub-pad of the first contact pad
32 second sub-pad of the first contact pad
91 first sub-pad of the second contact pad
92 second sub-pad of the second contact pad
100 welding machine
101 first welding contact
102 second welding contact
301 metal layer
302 structured metal layer

1. A method for establishing an electric connection, comprising:
providing an electronic component having a first welding part;
providing a first electrical contact piece; and
bringing into mechanical contact the first welding part and the first electrical contact piece,
while maintaining the mechanical contacting applying a welding current, which is capable of welding the first electrical contact piece and the first welding part together.

2. The method according to claim 1, wherein the first welding part is part of a first terminal electrode of the electronic component.

3. The method according to claim 1, wherein the first electrical contact piece is a first contact pad or part of a contact pad arranged on a carrier substrate.

4. The method according to claim 1, wherein upholding the mechanical contact during the welding is supported by pressing together the welding part and the electrical contact piece.

5. The method according to claim 1, wherein the first electrical contact piece and/or the first welding part comprises welding bumps which are capable of channeling a welding current through them to create a local welding spot.

6. The method according to claim 1, wherein a first and a second welding spot is formed simultaneously by the same welding current.

7. The method according to claim 1, wherein the method is applied subsequently or simultaneously to two terminal electrodes being welded to two separate contact pads on the same carrier substrate.

8. The method according to claim 1, wherein the outermost metal of the welding part and the electrical contact piece are the same.

9. The method according to claim 8, wherein the electrical contact piece or the welding part comprises silver, gold, copper, nickel, molybdenum or tungsten.

10. A chip Chip-assembly comprising;
an electronic component assembled on a carrier substrate, wherein
a first contact pad of the substrate is welded to a first terminal electrode of the electronic component to form an electrical connection.

11. The chip Chip-assembly according to claim 10, wherein the first contact pad encompasses two separate sub-pads and the first terminal electrode is welded to both sub-pads.

12. The chip Chip-assembly according to claim 10, wherein the electronic component comprises a second terminal electrode which is welded to a second contact pad on the carrier substrate.

13. The chip assembly according to claim 10, wherein the first contact pad is connected to connective means for integration of the same into an electronic circuit.

14. The chip assembly according to claim 10, wherein a welding spot connects the first terminal electrode and the first contact pad.

15. The chip assembly according to claim 10, wherein the outermost metal of the first terminal electrode and first contact pad are the same.

16. The chip assembly according to claim 15, wherein the first terminal electrode and first contact pad comprises silver, gold, copper, nickel, molybdenum or tungsten.

17. The chip assembly according to claim 10, wherein the first contact pad comprises two sub-pads, which are electrically bridged by one terminal electrode of the electronic component, and wherein the two sub-pads are electrically and spatially separated except for the electrical bridge by the terminal electrode.

18. Using the chip assembly according to claim 11, wherein a connection for integration of the same into an electronic circuit is performed by one sub-pad of the first contact pad only.
